(19) United States
(12) Patent Application Publication
(10) Pub. No.: US 2006/0212234 A1
(43) Pub. Date: Sep. 21, 2006

(54) Modular data recording and display unit

(76) Inventors: Wendelin Egli, Seuzach (CH); Andreas Reinhard, Zurich (CH)

Correspondence Address: JENKENS & GILCHRIST, PC, 1445 ROSS AVENUE, SUITE 3200, DALLAS, TX, 75202, US

(21) Appl. No.: 10/564,350

(22) PCT Filed: Jun. 16, 2004
(86) PCT No.: PCT/CH04/00362

§ 371 Date: Apr. 7, 2006

(30) Foreign Application Priority Data
Jul. 16, 2003 (CH) 01246/03

(51) Int. Cl. G01R 15/00

(52) U.S. Cl. 702/57

(57) ABSTRACT

The invention relates to a modular data recording and display unit. A module (4) essentially comprises a sensor (5), a controller (10) and a memory (11). The controller (10) processed the data recorded and transmitted by the sensor (5) and records the same in the memory (11). One or several types of sensors (5) may be connected depending on the module (4), for example with differing measuring ranges or differing measuring parameters. The multiplicity of connection possibilities and data formats can make the provision of further components, such as transmitter (6), receiver (7), amplifier (8) and converter (9) necessary between a sensor (5) and a controller (10). The controller (10) for the module (4) is configured and controlled by means of a control bus (12). The measured data stored in the memory (11) are read off using a separate data bus (13).

This invention relates to an expandable and adaptable data recording and display unit according to the preamble to claim 1.

EP 0 992 923 represents the nearest state of the art. The document discloses a system with a modular structure for recording data, as well as for its processing and storage. The individual modules are connected by a bus and can be configured by means of that bus. Intercommunication between the modules is also made possible. The individual modules function practically autonomously.

The disadvantage of the high degree of autonomy of the individual modules is that although the modules form an association of measuring instruments, they do not form an individual measuring instrument which, as a unit, monitors and/or records a process or several processes running in parallel.

The object of this invention is to disclose an easily expandable, adaptable data recording and display unit which allows a plurality of sensor combinations by simple means and supplies measurement results that are synchronised in time.

The achievement of this object is reproduced in the characterising part of the independent claim in respect of its essential characteristics, and in the dependent claims in respect of further advantageous characteristics. The data recording and display unit according to the invention is constructed from a main circuit board and further circuit boards that can be connected to it. One circuit board forms a so-called unit; correspondingly the main circuit board forms the main unit or the so-called basic unit. A unit is in turn formed by one or more modules, one module comprising the hardware for recording and storing data. The units are connected to each other by means of a bus. The basic unit is provided with an interface with a computer, from where the data recording and display unit can be controlled alternatively by means of software.

The data recording and display unit is explained in greater detail with reference to the following figures.

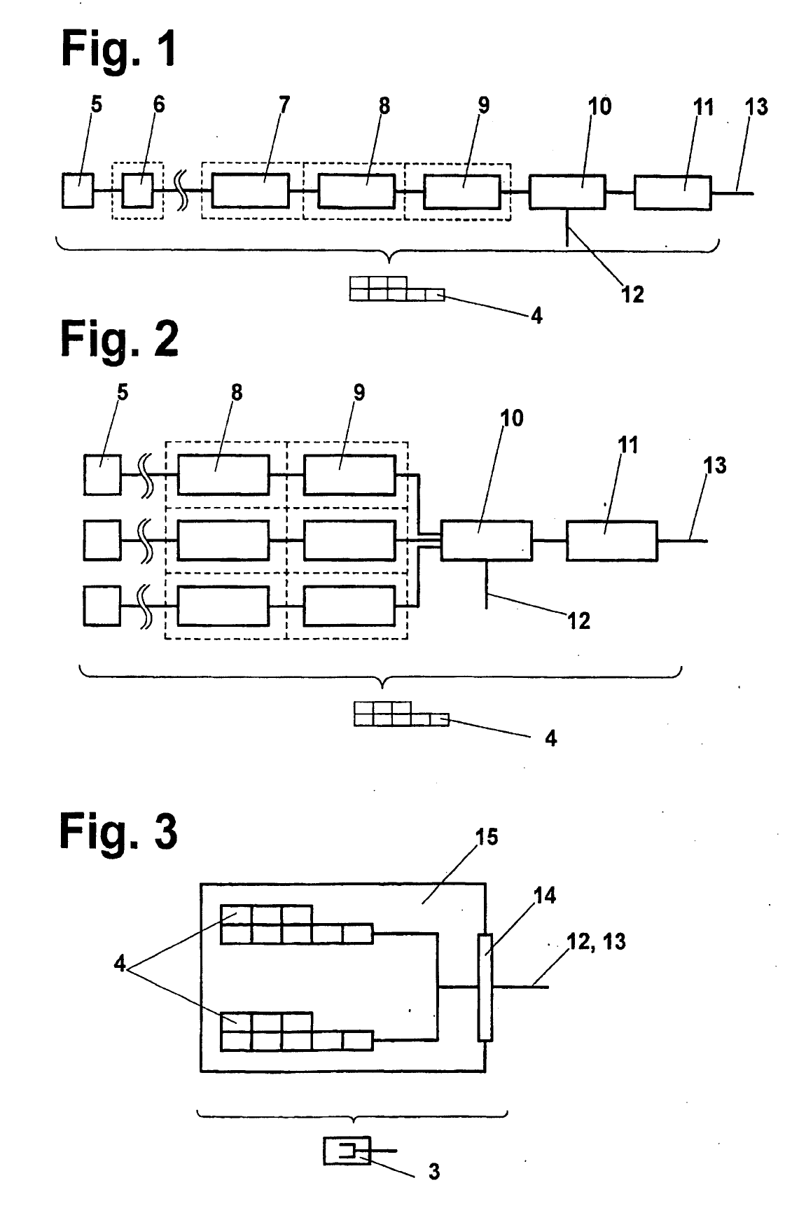

FIGS. 1, 2 show diagrammatic representations of modules,

FIG. 3 shows a diagrammatic representation of a unit,

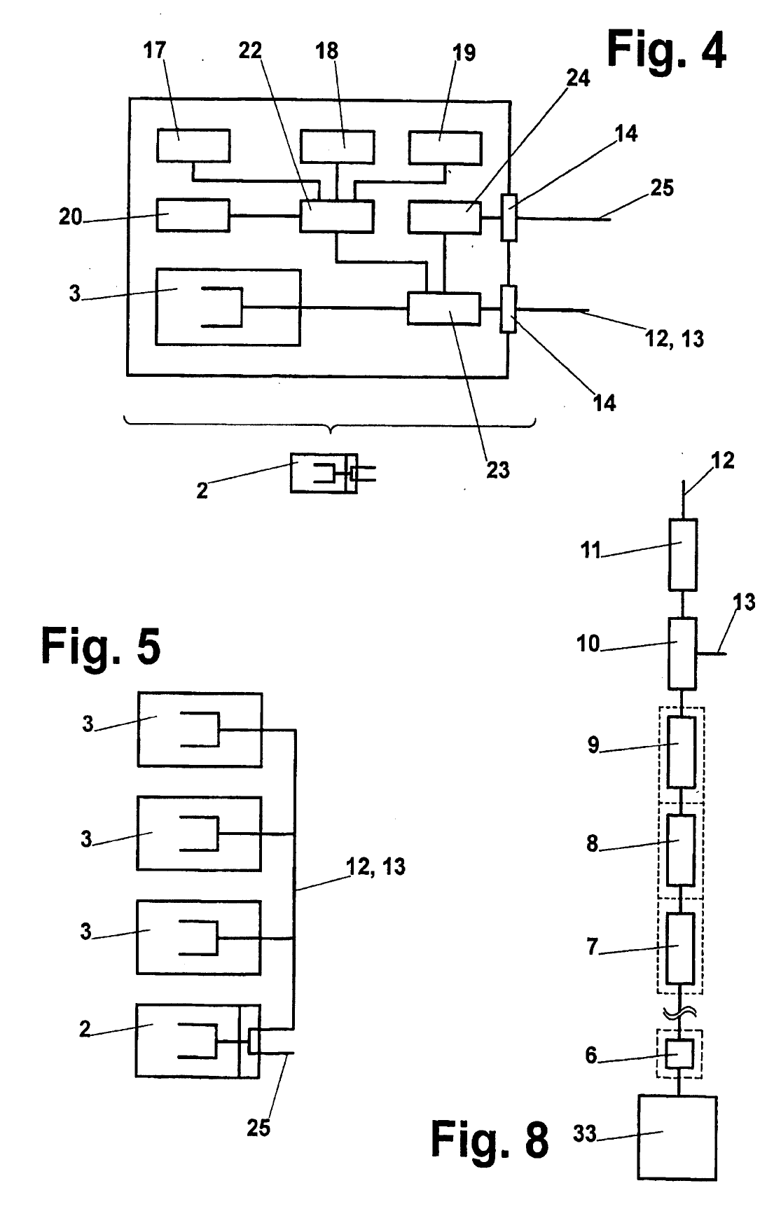

FIG. 4 shows a diagrammatic representation of a basic unit,

FIG. 5 shows a diagrammatic representation of a data recording and display unit according to the invention,

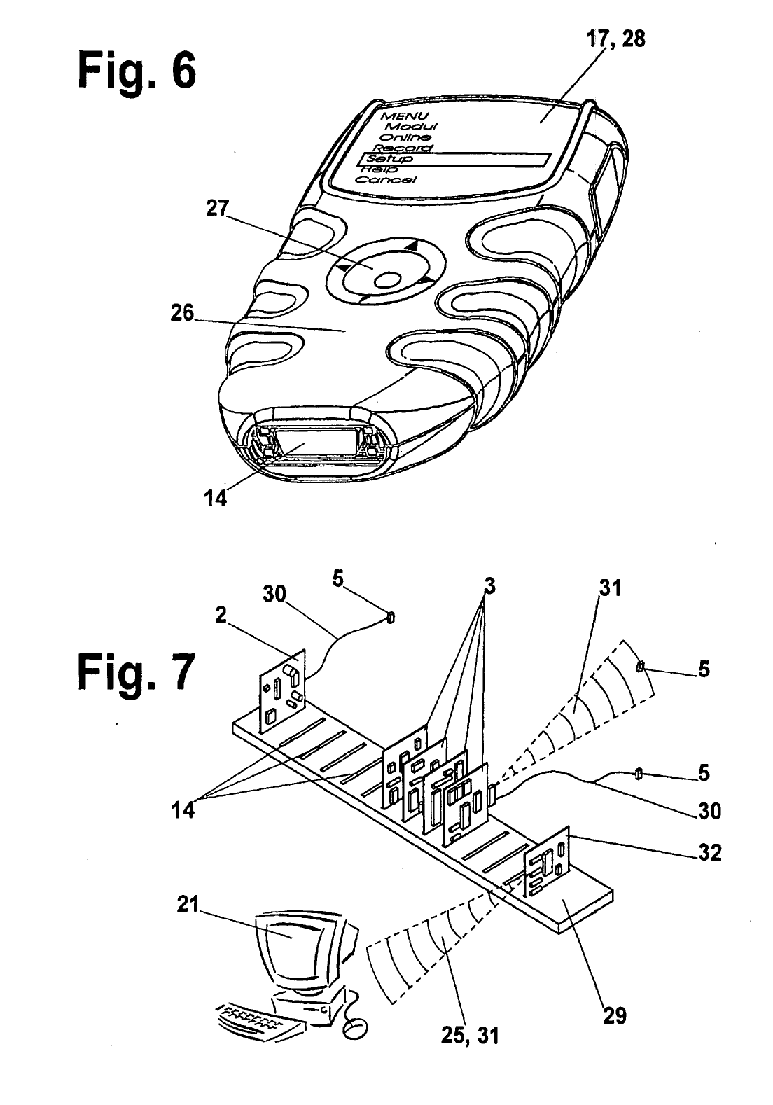

FIG. 6 shows a portable version of the data recording and display unit,

FIG. 7 shows a laboratory version of the data recording and display unit,

FIG. 8 shows a module for incorporating a measuring instrument, and

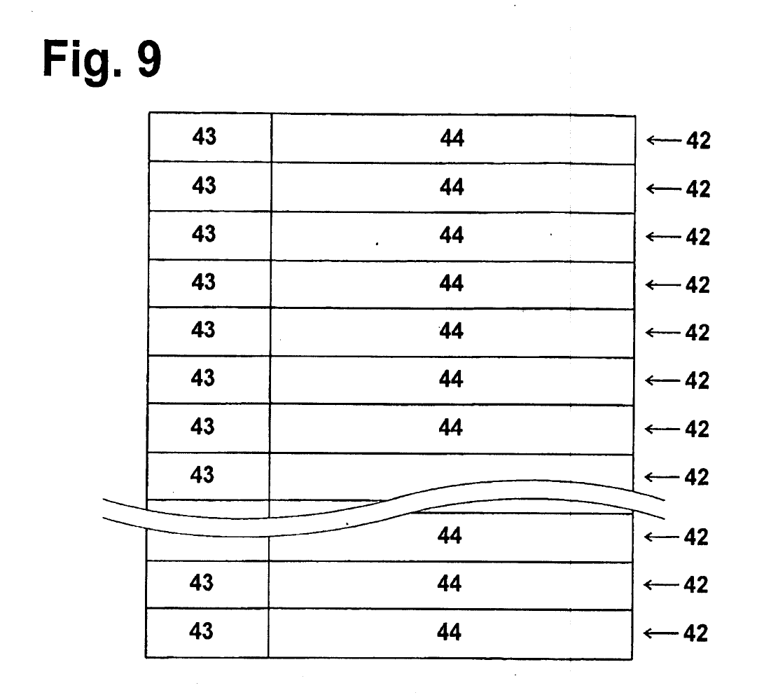

FIG. 9 shows a diagrammatic representation of the memory configuration.

FIG. 1 shows in highly diagrammatic fashion the structure of a module 4. A module 4 essentially comprises a sensor 5, a controller 10 and a memory 11. Controller 10 processes the data recorded and transmitted by sensor 5 and stores the same in memory 11. One or more types of sensors 5 may be connected, depending on module 4, e.g. sensors with different measuring ranges or different measured values. The form of connection from sensor 5 to controller 10 is dependent on the module. Modules 4 may be equipped for cable connections and/or for wireless connections, for example radio and infrared connections, and even fibre-optic connections. The format of the measured data to be transmitted may be analogue or digital. The multiplicity of connection possibilities and data formats may necessitate the provision, between a sensor 5 and a controller 10, of further components such as transmitter 6, transmitter 7, amplifier 8 and converter 9, represented in FIG. 1 as surrounded by broken lines. Each of the components surrounded by broken lines, as well as the sequence shown in FIG. 1, must be regarded as optional. In modern sensors 5 and controllers 10 elements corresponding to the components described as optional may already be installed and integrated.

FIG. 2 shows diagrammatically a module 4 with three sensors 5, for example. The three sensors 5 in module 4 may be similar to each other or may be different from each other. Amplifiers 8 and converters 9 are also optional. The data from the different sensors 7 are processed in controller 10 of module 4 and stored in memory 11. Non-volatile memories, for example Flash, E²PROM or NVRAM, but also optically active crystals, are suitable for constituting memory 11. Miniaturised hard disks may also be d.

Controllers 10 of modules 4 in FIGS. 1, 2 are configured and controlled by means of a control bus 12. The measured data stored in memories 11 are read by a separate data bus 13. Data bus 13 is provided with its own cables with which a point-to-point connection is made, which allows rapid data transfer of the frequently large quantities of data from measurement series. Obviously an individual bus may simultaneously perform the functions of the control and data bus 12, 13, but the functional distribution is logical.

FIG. 3 shows diagrammatically a unit 3. A unit 3 comprises one or more modules 4. Furthermore, a unit 3 is a unit that can be installed in and removed from a data recording and display unit 1. A unit 3 essentially comprises a printed circuit board 15 and the components of modules 4 soldered onto the board, for example. Exceptions to those are sensors 5, which frequently are obviously not installed directly on circuit board 15 but are installed directly at the location of measurement, from where they transmit their measured data via a cable connection to the other components of its module 4, for example. Unit 3, or circuit board 15, is connected to a further unit 3 by means of a plug connection 14, for example. At the same time the plug connection guarantees the physical connection between units 3, as well as the electronic connections between modules 4, which are made by means of control and data bus 12, 13.

Basic unit 2, shown in FIG. 4, constitutes a special case of unit 3. It comprises several modules 4 of a unit 3, as already explained in FIG. 3, and additional elements which together form a fully functional data recording and display unit 1 with a minimal scope of application. For example, the three modules 4 on basic unit 2 are equipped with sensors 5 for measuring triaxial accelerations, pressure and temperature. The additional elements are preferably an indicating module 17 and an input module 18, one or more LED's 19 and a real time clock 20, together with a controller 22 controlling these elements 17, 18, 19 and 20. Controller 22 is connected by means of control bus 12 to a further controller, communications controller 23, and controllers 10 on basic unit 2, as well as any units 3 connected. Communications controller 23 is also connected by means of data bus 13 to all memories 11 in basic unit 2, as well as to units 3. Plug connections 14 in turn facilitate assembly with further units 3.

Real time clock 20 is particularly important for data recording and display unit 1 according to the invention. Its cycle is transmitted to all controllers 10 on basic unit 2 and units 3 by means of control bus 12. The time intervals and times configured in individual controllers 10 for measurement series are calculated on the basis of this cycle. In this manner a certain time is defined accurately and clearly for all modules 4 collectively, and measurement series from different sensors 5 are time-correlated.

A commercially available liquid crystal indicator, for example, is suitable for use as an indicating module. Control elements 18 include all means such as buttons, switches and other input devices for operating with data recording and display unit 1. If a touch-sensitive screen is used as indicating module 17, this also forms part of control elements 18 at the same time. LED's 19 are used, for example, to indicate the operating status of data recording and display unit 1. Communications controller 23 controls the outside communication with a computer 21, by means of a signal converter 24, for example through the use of a serial interface 25, e.g. RS-232-C, USB, IEEE-1394 (FireWire) or a parallel interface 25, e.g. IEEE-1284, SCSI.

FIG. 5 shows diagrammatically a possible structure of data recording and display unit 1, which in this case comprises basic unit 2 and three units 3. Basic unit 2 is connected to the three units 3 by means of control bus 12 and data bus 13, thereby guaranteeing the communication between basic unit 2 and units 3.

In order to distribute the functions perfectly among the individual modules 4, all the hardware is provided for a multi-master operation. The individual modules 4 on basic unit 2 or units 3 may be configured individually or in groups as master or slave. For example, any module 4 may take over control via control bus 12, but the bus can also be divided with communications controller 23, for example. This configuration also permits the use of transmitter modules 32, for example. A transmitter module 32 can, for example, read the measured data from the different memories 11 instead of communications controller 23, by means of data bus 13, and transmit the data to a computer. In this case the method of transmission may be freely selected with transmitter module 32. WLAN and Bluetooth, for example, may therefore be easily integrated, as may radio, IR and other means such as fibre-optics.

FIG. 6 shows a first design of data recording and display unit 1, with a housing 26 which, although limiting the possibilities of expansion with additional units 3 to two to three, is extremely convenient for this purpose. For example, housing 26 is able to accommodate basic unit 2, with the three units 3, shown in FIG. 5. This design is ideal for mobile use and measurement series for which a limited set of sensors 5 is sufficient. In order to overcome the spatial limitations of housing 26, it is provided with a plug connection 14. Further units may also be connected outside housing 26. Data recording and display unit 1 can be controlled by a multi-function switch 27, wherein the desired information can be displayed and selected on a liquid crystal screen 28.

FIG. 7 shows a second design of data recording and display unit 1, which is ideal for use in the laboratory field. A plurality of plug connections is installed on a baseplate 29, into which connections basic unit 2 and units 3 may be inserted for fixing and connection to the data and control bus. This design permits the use of a plurality of units 3, individual units 3 being inserted and removed without appreciable expenditure. Obviously basic unit 2 and units 3 may of course only be connected together by cables for data transmission without a baseplate 29, which is often normal for experimenters in the laboratory and research fields. Here a computer 21 connected to the laboratory unit may be used instead of indicating module 17 and control elements 18 for the display and input of measurement and configuration data. The connection from computer 21 is guaranteed by transmitter module 32. As further illustration three sensors 5 are shown, two of them being connected by means of a cable 30 and one by means of a wireless connection 31 to corresponding modules 4.

The two embodiments in FIGS. 6, 7 illustrate the wide range of application of data recording and display unit 1. Like the laboratory unit, the hand unit is configured by a computer 21, but can otherwise be operated autonomously. The measured data can of course be transferred in turn from the hand unit to computer 21 and stored there. For example, the configuration of many modules 4 by means of the laboratory unit shown with computer 21 in FIG. 7, is extremely convenient for an extensive measurement, since a mouse and keyboard of computer 21 can be used for the inputs, for example. For the concept of the invention it is essential that despite the diversity of the hand and laboratory unit, it is one and the same data recording and display unit 1, which is constructed from exactly the same basic unit 2 and the same units 3.

FIG. 8 shows one special case of a module 4. Instead of one or more sensors a complete measuring instrument 33 is connected to module 4. An amplifier 8 and/or a converter 9 may also be incorporated in module 4 according to the type and format of the data of measuring instrument 33. Measuring instrument 33 supplies measured data or makes data available, which are read by controller 10 at predetermined times and stored by it. If measuring instrument 33 were to be connected in parallel, e.g. to data recording and display unit 1 according to the invention, for recording a measurement series as an independent unit, there would be a poorer time correlation of the measured data from measuring instrument 33 with the measured data from data recording and display unit 1 than if measuring instrument 33 were to be connected, as a sensor, to its module 4 of data recording and display unit 1. For example, it is possible with this incorporation method to synchronise a commercially available heart frequency meter together with a module 4 specially produced for this on a unit 3 with the remaining sensors in data recording and display unit 1. What is here the essential element of the invention is not the type of measuring instrument 13 but the method of incorporation of the same in a module 4 in the sense of one or more sensors 5.

The many applications of data recording and display unit 1 also include its use as a data recorder in a motor vehicle or aircraft, for example. To withstand a collision or crash, special requirements are associated with the components of data recording and display unit 1. Major effects of force and heat, as well as pressure loads, must not irrecoverably damage data recording and display unit 1, or in particular the stored data. On the one hand this is achieved with a special design, and on the other with a reproducible data protection system.

For example, memories 11 may be surrounded by a ceramic heat shield. In addition, modules 4 may be cast in resin. On the one hand the resin has elastic properties which protect modules 4 under the effects of force, and on the other, when the resin is melted by the effects of heat, the melting heat is removed from the area surrounding the resin, thereby protecting modules 4 and in particular memories 11 from heat. The configuration of the memory is reproduced in FIG. 9. The entire storage space of a memory 11 is divided into pages 42. Each page 42 is further subdivided into a header 43 and a data area 44. Configuration data from the measured data stored in data area 44 are stored in header 43. The configuration data include, for example, information on the unit of the measured data, or on the number of sensors and the sensors which recorded the information. The measured data are in addition always stored together with the time of the measurement, the time being defined by the real time clock on basic unit 2. This configuration of the memory now permits a memory 11 to be removed from module 4, and to be read elsewhere, for example on an identical module. The original measurement can be reconstructed from the combination of the configuration and measured data, and also time-correlated with data from other memories. Data recording and display unit 1 obviously also enables a unit 3, and hence also its modules 4, to be connected several times so that data can be recorded redundantly, thereby further improving a data reconstruction.

Since data recording and display unit 1 supports any combination of units, the manoeuvring of an aircraft and the state of health of the pilot/s may also be simultaneously recorded, for example, on the basis of selected medically relevant values.

Data recording and display unit 1 is controlled and configured by a control program. The configuration is carried out by a setup component, data are read by a reader component, measured data are displayed by a viewer component and finally measured data are indicated by an online component. The control program and its components are distributed among a computer 21 which can be connected via interface 25 to data recording and display unit 1, controllers 11 connected by control bus 12, communications controller 23 connected to control and data bus 12, 13, and controller 22 also connected to control bus 12.

The individual program components and their particular characteristics are examined in the following sections. The term routine is used in the following for parts of the program components, for example the setup routine of a controller 11, which is understood to mean that part of the setup component which runs in a controller 11.

In a first stage the setup component establishes which modules 4 are actually present and enables modules 4 present to be configured. For reasons of better operability and clarity of arrangement the individual modules 4 are only configured on the connected computer 21.

In the first stage, immediately after data recording and display unit 1 is switched on, all modules 4 run in parallel through their own setup routine, each module 4 establishing its own current configuration. For example, a module 4 may be designed so that three temperature sensors 5 can be connected. Furthermore, two types of temperature sensors 5 may be selected. The setup routine of module 4 will now establish how many temperature sensors 5 are present and what type they are. Moreover, the setup routine will attempt to re-use the last stored configuration data, e.g. measurement intervals. If a sensor 5 is removed, its configuration data are not available but they are not deleted either, and can therefore be made available again at a later time. If a sensor 5, corresponding to the last removed type, is added, the stored configuration data are re-used. If added sensor 5 is of a different type, it must be reconfigured of a standard configuration is carried out. If a sensor 5 is abandoned, its configuration corresponds to the last configuration stored.

In the second stage the setup routine of computer 21 asks controller 22 which modules 4 are present. Controller 22 then asks each module sequentially to release the configuration data recorded in the first stage, whereupon they are read by the setup routine of computer 21. In this manner the setup component learn which modules 4 are currently present in data recording and display unit 1, and how they are configured. If, for example, a unit 3 has been removed, at least one module 4 less will be present.

The configuration options and values can be represented graphically for modules 4 and sensors 5 recorded in the second stage. It is therefore only possible to configure modules 4 and sensors 5 which are also actually present. For example, whole modules 4 or individual sensors 5 can be activated or deactivated, and measurement ranges and intervals also form part of the scope of configuration. It is important that each module has its own specific configuration options. These options are defined one the one hand by sensor or sensors 5, and on the other by the module itself. For example, a module 4 can be constructed so that a maximum of three connectable temperature sensors 5 must be of the same type and configured the same way. The new configuration values are stored in modules 4 at the end of a configuration process.

The setup component uses exclusively control bus 12 as the communication medium.

The limitation that data recording and display unit 1 can only be configured by computer 21 not only results in greater operating comfort, but has the further advantage that controller 22 need not interpret the configuration data and need not therefore be considered when integrating new modules 4 or whole units 3. Obviously it is easily possible for the programming specialist to develop a setup routine for master 22, for example, which is why this design also forms part of the concept of the invention.

The reader component is responsible for reading the measured data from memories 11 and storing the measured data in files on computer 21. For this purpose the reader routine of computer 21 informs controller 22 the measured data it wants from which modules 4, for example all the measured data from a particular measurement series, or all the measured data from a certain module 4 or sensor 5. Controller 22 then instructs the modules concerned sequentially to place the required measured data together with the configuration data on data bus 13, from where they can be fed via communications controller 23 directly into the computer and stored in it. The data may on the one hand be stored in an MRS format specially developed for data recording and display unit 1, but on the other hand the data may also be stored in formats of prior art, for example CVS, which guarantees the portability of the data to other systems.

The viewer component is responsible for the graphic representation of the measured data on computer 21. It opens the MSR files and represents graphically the measured data stored in them, taking into consideration the configuration data. The viewer component makes many observation tools available, but from the computer point of view these tools belong to the state of the art and will not be discussed in greater detail.

The online component may display current measured values during a measurement or for testing a configuration on a display module 17. On the page of computer 21 the measured values of all active sensors 5 can be represented and monitored in parallel. On the other hand, data recording and display unit 1 only represents the data from a single sensor. However, the possibility of representing several or all measured values in parallel on data recording and display unit 1 also forms part of the concept of the invention, since the implementation presents no insurmountable problems to the experienced programmer. The current measured data is transmitted by communications controller 23 via control bus 12, and are then fed either to controller 22 or via interface 25 to computer 21, or even both.

The computer components of the control programme are network ready. For example, it is therefore possible to operate and control data recording and display unit 1 from a workstation without restrictions, or to monitor a measurement in progress.

1. A data recording and display unit (1) that can be connected
for data exchange by means of a communications controller (23) and a signal converter (24) to a serial or parallel interface (25) of a computer (21), consisting of various units (3) and a basic unit (2), which are connected to each other by a control bus (12) and a data bus (13), and are synchronised by means of a single real time clock (20) on the basic unit, and of at least one module (4) which
comprises at least a sensor (5), a controller (10) and a memory (11) for recording and storing data,
optionally may have a transmitter and receiver, amplifier, converter or combinations thereof between sensor (5) and controller (10),
stores in its memory (11) each measuring point together with the clear time of the measurement generated by the real time clock (2),
characterised in that
even without an exchange of modules many sensor combinations are made possible by connecting different combinations of sensors to a module,
the modules (4) themselves record the sensor combinations connected to them by carrying out a setup routine after the unit (1) is switched on,
the configuration data for the individual sensors (5) remain stored to enable sensors (5) already configured to be connected or omitted without this necessitating a reconfiguration on the PC (21).

2. The data recording and display unit (1) according to claim 1, characterised in that
commercially available measuring instruments can be incorporated in the same way as sensors by means of special modules, and supply measured values synchronised by this method of incorporation with the other modules installed.

3. The data recording and display unit (1) according to claim 1, characterised in that
the control bus (12) connects the controller (22) to the communications controller (23) and the controllers (10) on the basic unit (2) and the units (3),
a data bus connects all the memories (11) on the basic unit (2) and the units (3) directly to the communications controller (23).

4. The data recording and display unit (1) according to claim 3, characterised in that a module (4) is present on the basic (2) for measuring each of the following: triaxial accelerations, pressure and temperature.

5. The data recording and display unit (1) according to claim 1, characterised in that any module (4), for example a transmitter module, is able to take over control of the control bus, wholly or in part (Multi-master operation).

6. The data recording and display unit (1) according to claim 5, characterised in that
a transmitter module is able to read the measured data via the data bus (13) and transmit the data to a computer (21),
the transmission method (WLAN, Bluetooth, radio, etc.) can be freely selected by means of corresponding modules.

7. The data recording and display unit (1) according to claim 4, characterised in that
the basic unit is installed in an easy to handle housing (26),
the display module (17) and the control elements (18) of the basic unit (2) are also integrated in the housing (26),
a plug connection is integrated in the housing (26) so that further units may be connected.

8. The data recording and display unit (1) according to claim 3, characterised in that a plurality of plug connections (14) is installed on a base plate (29), into which connections the basic unit (2) and units (3) may be inserted for fixing and for connecting to control bus (12) and data bus (13).

9. The data recording and display unit (1) according to claim 6 and any one of claims 5 or 6, characterised in that it can record data from a motor vehicle or aircraft.

10. The data recording and display unit (1) according to claim 6 any one of claims 5 or 6, characterised in that it can record medical and/or sports medical data.

11. The data recording and display unit (1) according to claim 1, characterised in that the memories (11) of the modules (4) are divided into pages (42), which in turn each consist of a header (43) and a data area (44), in that configuration data from a measurement are stored in the header (43) and the measured data together with the times of the measurement are stored in the data area (44), so that the measurement can only be reproduced from the data in the memories (11).

12. The data recording and display unit (1) according to claim 1, characterised in that the modules (4) are able to withstand major force and heat influences without damage due to a special method of construction, for example casting in resin and equipping with ceramic heat shields.

13. A control program for a data recording and display unit (1) according to any one of the preceding claims, which unit comprises the network ready components setup, reader, viewer and online, characterised in that
the online component enables the measured data from all the sensors to be displayed in parallel in real time on the PC (21) both as raw data and graphically,
the user surface on the PC (21) is automatically adapted so that for the modules (4) and sensors (5) recorded by the setup component a graphic interface is made available for the configuration of the same, and so that only the components that are actually connected can be configured.
